(19) United States
(12) Patent Application Publication
(10) Pub. No.: US 2026/0239706 A1
(43) Pub. Date: Aug. 13, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Kohei OASA, Setagaya Tokyo (JP); Tatsuya NISHIWAKI, Yokohama Kanagawa (JP); Kentaro ICHINOSEKI, Higashimurayama Tokyo (JP)

(21) Appl. No.: 19/355,896

(22) Filed: Oct. 10, 2025

(30) Foreign Application Priority Data
Feb. 12, 2025 (JP) 2025-020720

(51) Int. Cl. H10D 64/00; H10D 30/66; H10D 62/10

(52) U.S. Cl. CPC H10D 64/117; H10D 30/668; H10D 62/127

(57) ABSTRACT

A semiconductor device of an embodiment includes a semiconductor member, a source electrode, a plurality of field plate electrodes that extend in a first direction, a gate electrode, and a gate wiring. The plurality of field plate electrodes are electrically connected to the source electrode. The gate electrode has a plurality of first extension portions that extend in a second direction. The gate wiring has a plurality of second extension portions that extend in the second direction. Each second extension portion is connected to a corresponding first extension portion at a position inside a formation region in which the plurality of field plate electrodes are formed, and extends in the second direction from a portion connected to the first extension portion to a position outside the formation region. The source electrode and the plurality of second extension portions are disposed at different positions in the first direction.

### CROSS-REFERENCE TO RELATED APPLICATION

This application is based upon and claims the benefit of priority from Japanese Patent Application No. 2025-020720, filed on February 12, 2025; the entire contents of which are incorporated herein by reference.

### FIELD

Embodiments described herein relate generally to a semiconductor device.

### BACKGROUND

A semiconductor device that includes a plurality of field plate electrodes electrically connected to a source electrode is known. The plurality of field plate electrodes may be disposed to be spaced apart from each other, for example, at a plurality of locations in two directions that intersect a thickness direction of the semiconductor device and intersect each other. In such a semiconductor device, as seen in the thickness direction of the semiconductor device, when a gate electrode is disposed outside a formation region in which the plurality of field plate electrodes are formed, the voltage of a drain electrode may be applied to an insulation film covering the gate electrode, causing dielectric breakdown in the insulation film.

To address the above problem, a configuration may be adopted in which, when seen in the thickness direction of the semiconductor device, the gate electrode is disposed inside the formation region in which the plurality of field plate electrodes are formed, and the gate electrode is electrically connected via a gate wiring to a contact wiring formed outside the formation region. In this case, the gate electrode has, for example, a plurality of first extension portions that extend in a direction intersecting the thickness direction of the semiconductor device. The plurality of first extension portions are arranged at intervals in a direction that intersects both an extension direction of the plurality of first extension portions and the thickness direction of the semiconductor device. The gate wiring has a plurality of second extension portions that extend from the outside to the inside of the formation region. The plurality of second extension portions are electrically connected to the plurality of first extension portions, respectively.

The plurality of second extension portions of the gate wiring as described above are disposed, for example, in a plurality of gap portions formed in the source electrode. In this case, in order to ensure an insulation distance between the source electrode and the plurality of second extension portions, it was necessary to arrange each of the plurality of second extension portions at a certain distance from edges of the plurality of gap portions formed in the source electrode. Thus, it is necessary to increase the distance between the second extension portions by the distance between each of the edges of the gap portions and each of the second extension portions, which imposes restrictions on the distance between the second extension portions. As a result, restrictions are imposed on the distance between the plurality of first extension portions to which the plurality of second extension portions are respectively connected. Therefore, there are also restrictions on a pitch between the first extension portions in a direction in which the plurality of first extension portions of the gate electrode are arranged, that is, a cell pitch of the semiconductor device. As a result, there is a problem that it becomes difficult to reduce on-resistance of the semiconductor device.

### BRIEF DESCRIPTION OF THE DRAWINGS

FIG. 1 is a plan view showing a part of a semiconductor device according to a first embodiment, and is a cross-sectional view taken along line I-I in FIG. 2.

FIG. 2 is a cross-sectional view taken along line II-II in FIG. 1.

FIG. 3 is a cross-sectional view taken along line III-III in FIG. 1.

FIG. 4 is an enlarged plan view of a source electrode and an end portion of a gate wiring according to the first embodiment.

FIG. 5 is an enlarged plan view of a source electrode and an end portion of a gate wiring according to a second embodiment.

FIG. 6 is an enlarged plan view of a source electrode and an end portion of a gate wiring according to a third embodiment.

### DETAILED DESCRIPTION

A semiconductor device of an embodiment includes a semiconductor member having a drift layer having a first conductivity type, a source electrode located on one side of the semiconductor member in a first direction(a Z direction), a drain electrode located on the other side of the semiconductor member in the first direction, a plurality of field plate electrodes that extend in the first direction and at least parts of which are located inside the drift layer, a gate electrode at least a part of which is located inside the semiconductor member, and a gate wiring electrically connected to the gate electrode. The plurality of field plate electrodes are electrically connected to the source electrode, insulated from the semiconductor material via a first insulation film, and disposed to be spaced apart from each other at a plurality of locations in a second direction intersecting the first direction dopant concentration and a third direction intersecting both the first direction and the second direction. The semiconductor member has a base layer located on one side of the drift layer in the first direction and having a second conductivity type, and a source layer located on one side of the base layer in the first direction and having the first conductivity type. The gate electrode has a plurality of first extension portions extending in the second direction and is insulated from the semiconductor member via a second insulation film. The plurality of first extension portions are arranged at intervals in the third direction. At least a part of the gate electrode is disposed adjacent to the source layer and the base layer via the second insulation film. The source layer is electrically connected to the source electrode. The source electrode extends along a plane perpendicular to the first direction. The gate wiring has a plurality of second extension portions that extend in the second direction. The plurality of second extension portions are arranged at intervals in the third direction. Each second extension is connected to a corresponding first extension portion at a position that is inside a formation region defined by the matrix of field plate electrodes in which the plurality of field plate electrodes are formed when seen in the first direction, and extends on one side in the second direction from a portion connected to each of the first extension portions to a position that is outside the formation region when seen in the first direction. The source electrode and the second extension portions are disposed at different positions in the first direction.

Hereinafter, a semiconductor device according to an embodiment will be described with reference to the drawings. In the following description, components having the same or similar functions may be designated by the same reference numerals. Furthermore, duplicate descriptions of the components may be omitted.

### First embodiment

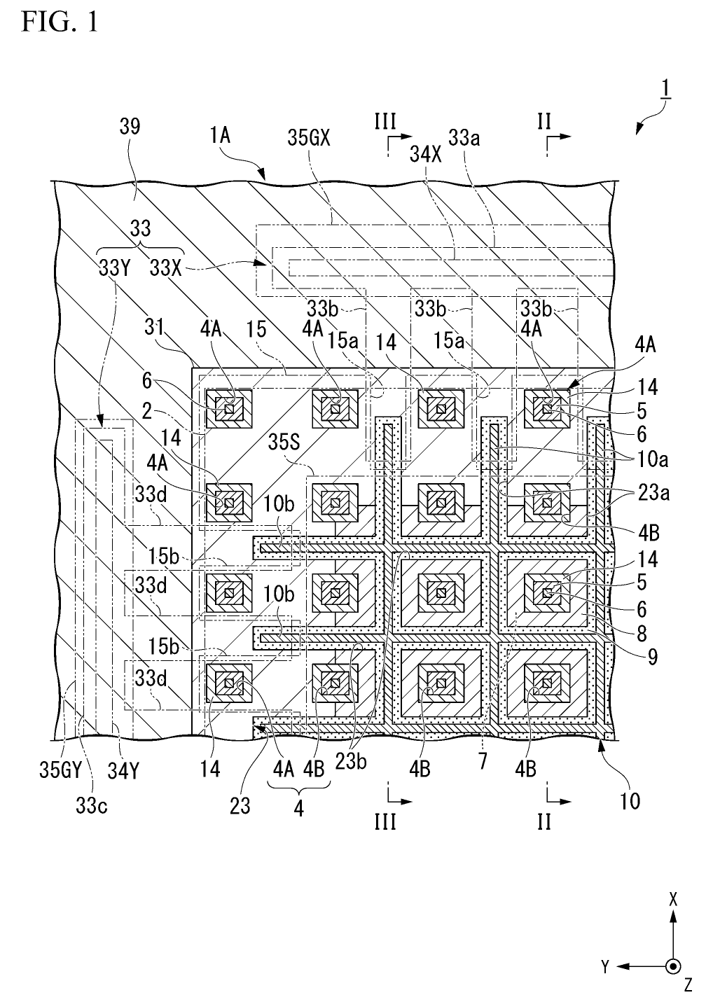

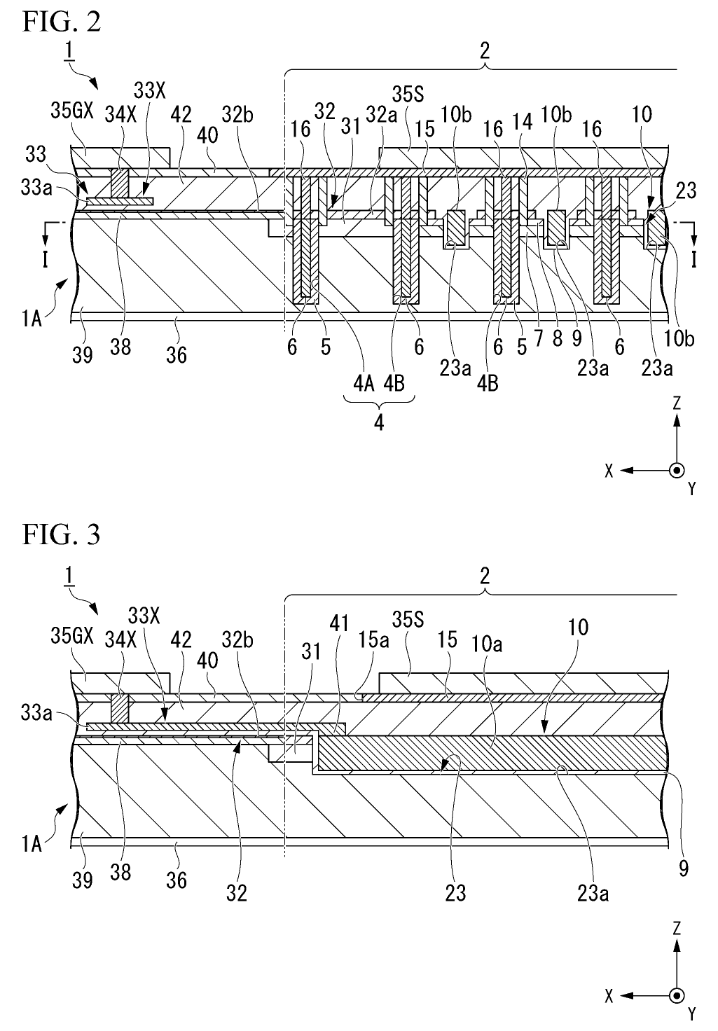

A configuration of a semiconductor device 1 in a first embodiment will be described below. FIG. 1 is a plan view showing a part of the semiconductor device 1. FIG. 2 is a cross-sectional view taken along line II-II in FIG. 1. FIG. 3 is a cross-sectional view taken along line III-III in FIG. 1.

In the following description, an up-down direction in FIG. 1 is defined as an X direction, a left-right direction in FIG. 1 is defined as a Y direction, and a direction perpendicular to the drawing in FIG. 1 and perpendicular to both the X direction and the Y direction is defined as a Z direction. The Z direction is a thickness direction of the semiconductor device 1. The X direction, the Y direction, and the Z direction are perpendicular to each other. In the following description, the Z direction corresponds to a “first direction.” The side (the +Z side) to which an arrow indicating the Z direction faces corresponds to the “one side in the first direction,” and the side (the -Z side) opposite to the side to which the arrow indicating the Z direction faces corresponds to the “other side in the first direction.”

The semiconductor device 1 in FIG. 1 is a power metal-oxide-semiconductor field-effect transistor (MOSFET). As shown in FIGS. 1 and 2, the semiconductor device 1 includes a semiconductor member 1A, a drain electrode 36, a source electrode 15, a plurality of field plate electrodes 6, a gate electrode 10, and a gate wiring 33.

The semiconductor member 1A is formed by adding impurities to a semiconductor material such as silicon (Si). As shown in FIG. 2, the semiconductor member 1A includes a drift layer 39 having an n-type impurity as a first conductivity type, a base layer 7 located on the +Z side of the drift layer 39 and having a p-type impurity as a second conductivity type, a source layer 8 located on the +Z side of the base layer 7 and having the n-type impurity as the first conductivity type, and a RESURF layer 31 having the p-type impurity as the second conductivity type. The first conductivity type may be a p-type impurity, and the second conductivity type may be an n-type impurity.

The drift layer 39 is a layer formed of, for example, an n⁻-type semiconductor. The base layer 7 is located on the +Z side of the drift layer 39. The base layer 7 is a layer formed of a p-type semiconductor. The source layer 8 is located on the +Z side of the base layer 7. The source layer 8 is a layer formed of an n⁺-type semiconductor.

In this specification, the terms “n⁺ type,” “n type” and “n⁻ type” used for semiconductors represent a relative magnitude relationship of an n-type carrier concentration of the semiconductor. An “n⁺-type” semiconductor has a higher n-type carrier concentration than an “n-type” semiconductor. An “n⁻-type” semiconductor has a lower n-type carrier concentration than the “n-type” semiconductor. The “carrier concentration” refers to an effective dopant concentration that contributes to conductivity of the semiconductor material. When a region contains both impurities that act as donors and impurities that act as acceptors, the “carrier concentration” corresponds to a net dopant concentration excluding offset amounts. In the first embodiment, the source layer 8 formed of the n⁺-type semiconductor has a relatively higher n-type dopant concentration, that is, a higher carrier concentration, than the drift layer 39 formed of the n⁻-type semiconductor.

The semiconductor member 1A includes a plurality of field plate trenches (hereinafter, referred to as FP trenches 4) and a gate trench 23. As shown in FIG. 1, the FP trenches 4 are disposed in a dot pattern when seen in the thickness direction of the semiconductor device 1, that is, in the Z direction. In the first embodiment, the plurality of FP trenches 4 are disposed in a matrix form at a plurality of locations on the semiconductor member 1A in the X and Y directions to be spaced apart from each other when seen in the Z direction. There is no particular limitation on a shape of each of the FP trenches 4 seen in the Z direction. As shown in FIG. 2, the FP trench 4 is formed to be recessed from a surface of the semiconductor member 1A on the +Z side to the -Z side. End portions of the plurality of FP trenches 4 on the -Z side are located on the -Z side with respect to the source layer 8 and the base layer 7. Portions of the plurality of FP trenches 4 on the -Z side are formed in the drift layer 39.

As shown in FIG. 1, among the plurality of FP trenches 4 disposed in a matrix form, the FP trenches 4 located at both ends in the X direction and the FP trenches 4 located at both ends in the Y direction are referred to as first FP trenches 4A. The plurality of first FP trenches 4A are disposed to surround the plurality of FP trenches 4 other than the first FP trench 4A when seen in the Z direction. Among the plurality of FP trenches 4, the other plurality of FP trenches 4 surrounded by the plurality of first FP trenches 4A when seen in the Z direction are referred to as second FP trenches 4B.

As shown in FIG. 2, a field plate insulation film 5 and a field plate electrode 6 are formed inside each of the FP trenches 4. The field plate electrode 6 extends in the Z direction. At least a part of the field plate electrode 6 is located inside the drift layer 39. In the first embodiment, a portion of the field plate electrode 6 located on the -Z side with respect to the base layer 7 is located inside the drift layer 39. An end portion of the field plate electrode 6 on the +Z side is connected to a plate contact 16 which will be described below.

The plurality of field plate electrodes 6 are electrically connected to the source electrode 15. In the first embodiment, the end portions of the plurality of field plate electrodes 6 on the +Z side are electrically connected to the source electrode 15 via the plurality of plate contacts 16, respectively. The plurality of plate contacts 16 are made of a metal. The plurality of plate contacts 16 are formed of, for example, a Ti/TiN/W laminated film. The plurality of plate contacts 16 may be made of other metals. Each of the plate contacts 16 penetrates an insulation film 42, which will be described below, in the Z direction, and electrically connects the source electrode 15 and the field plate electrode 6. The source electrode 15 is electrically connected to the field plate electrodes 6 in the plurality of FP trenches 4 via the plurality of plate contacts 16.

The field plate insulation film 5 is provided in a portion of each of the FP trenches 4 other than a portion in which the field plate electrode 6 is provided. Each of the field plate insulation films 5 is provided between an inner surface of each of the FP trenches 4 and each of the field plate electrodes 6. The field plate insulation film 5 is, for example, a silicon oxide film (other materials such as SiN may also be used.). Each of the field plate electrodes 6 is embedded in the semiconductor member 1A in a state in which it is insulated from the semiconductor member 1A via each of the field plate insulation films 5. In the first embodiment, the field plate insulation film 5 corresponds to a “first insulation film.”

In the first embodiment, edges of the base layer 7 and the source layer 8 on the +X side are provided at the same position in the X direction as a center portion in the X direction of the field plate electrode 6 in the second FP trench 4B located furthest on the +X side. Edges of the base layer 7 and the source layer 8 on the +Y side are provided at the same position in the Y direction as a center portion in the Y direction of the field plate electrode 6 in the second FP trench 4B located furthest on the +Y side. Although not shown, edges of the base layer 7 and the source layer 8 on the -X side are provided at the same position in the X direction as the center portion in the X direction of the field plate electrode 6 in the second FP trench 4B located furthest on the -X side. Although not shown, edges of the base layer 7 and the source layer 8 on the -Y side are located at the same position in the Y direction as the center portion in the Y direction of the field plate electrode 6 in the second FP trench 4B located furthest on the -Y side.

The RESURF layer 31 has p-type impurities as second conductive impurities. The RESURF layer 31 is a layer formed of a p⁻-type semiconductor. As shown in FIG. 2, the RESURF layer 31 is laminated on the +Z side of the drift layer 39. The RESURF layer 31 is located outside the base layer 7 and the source layer 8 when seen in the Z direction. The RESURF layer 31 surrounds the base layer 7 and the source layer 8 when seen in the Z direction. An outer edge of the RESURF layer 31 is located outside a formation region 2, which will be described below, when seen in the Z direction, and surrounds the formation region 2. The RESURF layer 31 is not an essential component and may not be provided, but is preferable because providing the RESURF layer 31 is expected to improve a breakdown voltage of the semiconductor device 1.

In this specification, the terms “p⁺ type,” “p type,” and “p⁻ type” used for semiconductors refer to a relative magnitude relationship of a p-type carrier concentration of the semiconductor. A “p⁺-type” semiconductor has a higher p-type carrier concentration than a “p-type” semiconductor. A “p⁻-type” semiconductor has a lower p-type carrier concentration than the “p-type” semiconductor. The RESURF layer 31 formed of a p⁻-type semiconductor has a relatively lower p-type dopant concentration, that is, carrier concentration, than the base layer 7 formed of a p-type semiconductor.

As shown in FIG. 1, when seen in the Z direction, a source contact 14 is formed around each of the field plate electrodes 6. The source contact 14 is made of a metal. The source contact 14 is formed of, for example, a Ti/TiN/W laminated film. The source contact 14 may be made of other metals. Each of the source contacts 14 surrounds an upper end portion of each of the field plate insulation films 5. As shown in FIG. 2, each of the source contacts 14 extends to the -Z side from the source electrode 15. Each of the source contacts 14 penetrates the insulation film 42, which will be described below, in the Z direction. Each of the source contacts 14 surrounds the end portion of the field plate electrode 6 on the +Z side and the plate contact 16. An end portion of the source contact 14 on the -Z side provided for the field plate electrode 6 in the second FP trench 4B penetrates the source layer 8 and is electrically connected to a surface of the base layer 7 on the +Z side. In the source contact 14 provided for the field plate electrode 6 in the second FP trench 4B, a portion that penetrates the source layer 8 is electrically connected to the source layer 8. Thus, the base layer 7 and the source layer 8 are electrically connected to the source electrode 15 via the source contact 14. As described above, in the first embodiment, the semiconductor device 1 includes a plurality of source contacts 14 electrically connected to the source electrode 15. The end portion of the source contact 14 on the -Z side provided for the field plate electrode 6 in the first FP trench 4A is connected to the RESURF layer 31.

As shown in FIG. 1, when seen in the Z direction, the formation region 2 in which the plurality of field plate electrodes 6 are formed is provided in the semiconductor device 1. In FIG. 1, the formation region 2 is indicated by a two-dot chain line. In the first embodiment, the formation region 2 is a region in which the plurality of field plate electrodes 6 and portions of the semiconductor device 1 provided for each of the plurality of field plate electrodes 6 are disposed in a matrix form when seen in the Z direction. In the first embodiment, the portions of the semiconductor device 1 provided for each of the plurality of field plate electrodes 6 include the field plate insulation film 5 and the source contact 14. An outer edge of the formation region 2 surrounds the plurality of field plate electrodes 6 and the plurality of source contacts 14 when seen in the Z direction. In the first embodiment, an outer edge of the formation region 2 is defined by an outer edge of the source contact 14 provided for the field plate electrode 6 in the plurality of first FP trenches 4A, when seen in the Z direction. When seen in the Z direction, the edge of the formation region 2 on the +X side passes through the edge of the source contact 14 on the +X side disposed at the end on the +X side, and extends in the Y direction. When seen in the Z direction, the edge of the formation region 2 on the +Y side passes through the edge of the source contact 14 on the +Y side disposed at the end on the +Y side, and extends in the X direction. Although not shown, when seen in the Z direction, an edge of the formation region 2 on the -X side extends in the Y direction through an edge of the source contact 14 on the -X side disposed at an end thereof on the -X side. Although not shown, when seen in the Z direction, an edge of the formation region 2 on the -Y side extends in the X direction through an edge of the source contact 14 on the -Y side disposed at an end thereof on the -Y side. In this way, in the first embodiment, when seen in the Z direction, the outer edge of the formation region 2 passes through outer edges of all of the source contacts 14 located at both ends in the X direction among the plurality of source contacts 14, and outer edges of all of the source contacts 14 located at both ends in the Y direction among the plurality of source contacts 14.

As shown in FIG. 2, the drain electrode 36 is located on the -Z side of the semiconductor member 1A. More specifically, the drain electrode 36 is located on the -Z side of the drift layer 39 of the semiconductor member 1A. The drain electrode 36 is made of a metal. The drain electrode 36 is formed of, for example, aluminum. The drain electrode 36 may be made of a metal other than aluminum, such as copper. The drain electrode 36 may be formed of, for example, a Cu/Al/Ni laminated film. Furthermore, a metal film formed of a Ti/TiN laminated film or the like may be provided as a barrier metal between the drain electrode 36 and the surface of the semiconductor member 1A on the -Z side.

A protective film 32 and the insulation film 42 are formed on the +Z side of the semiconductor member 1A. That is, the semiconductor device 1 includes the protective film 32 and the insulation film 42. The protective film 32 is formed on the entire +Z side of the semiconductor member 1A in the formation region 2 except for a portion in which the gate trench 23 is formed. The protective film 32 is formed on the surfaces of the RESURF layer 31 and the source layer 8 on the +Z side in the formation region 2. The protective film 32 is formed on a third insulation film 38, which will be described below, outside the formation region 2. That is, the protective film 32 has a portion 32b formed on a surface of the third insulation film 38 on the +Z side. A thickness of a portion 32b of the protective film 32 formed on the third insulation film 38 is thinner than a thickness of a portion 32a of the protective film 32 formed on the surfaces of the RESURF layer 31 and the source layer 8 on the +Z side. The protective film 32 is a film that has a barrier property against ions. “The fact that the protective film 32 has a barrier property against ions” means, for example, that the protective film 32 has a property that makes it more difficult for ions to move within the protective film 32 than within other films adjacent to the protective film 32. The protective film 32 is made of, for example, silicon nitride (SiN). Since the protective film 32 may be disposed to provide a barrier against ions and the like that may affect reliability, the reliability of the semiconductor device 1 can be improved. The protective film 32 does not have to have, for example, the portion 32a.

The insulation film 42 is, for example, a film formed of a silicon compound. The insulation film 42 is, for example, a TEOS film formed using tetra eth oxy silane (TEOS) as a raw material. The insulation film 42 is formed using, for example, a plasma chemical vapor deposition (CVD) method. The insulation film 42 is located on the +Z side of the protective film 32. The insulation film 42 is laminated on the +Z side of the protective film 32. A thickness of the insulation film 42 in the Z direction is greater than a thickness of the protective film 32 in the Z direction. The source electrode 15 is formed on the surface of the insulation film 42 on the +Z side.

The source electrode 15 is located on the +Z side of the semiconductor member 1A. The source electrode 15 extends along a plane perpendicular to the Z direction. As shown in FIG. 1, the source electrode 15 is disposed up to a position at which it can come into contact with the field plate electrode 6 in the plurality of first FP trenches 4A. The source electrode 15 is made of a metal. The source electrode 15 is formed of, for example, a Ti/TiN/W laminated film. The source electrode 15 may be made of other metals such as aluminum and copper. The source electrode 15 may be formed of, for example, a Cu/Al/Ni laminated film. Furthermore, a metal film formed of a Ti/TiN laminated film or the like may be provided as a barrier metal between the source electrode 15 and the surface of the semiconductor member 1A on the +Z side. As shown in FIG. 2, a contact wiring 35S is formed on the +Z side surface of the source electrode 15. The contact wiring 35S is made of a metal. The contact wiring 35S is made of, for example, aluminum. The contact wiring 35S may be made of a metal other than aluminum, such as copper. The contact wiring 35S is electrically connected to the source electrode 15. The contact wiring 35S is exposed on the surface of the semiconductor device 1. In FIG. 1, the source electrode 15 and the contact wiring 35S are indicated by two-dot chain lines.

As shown in FIG. 1, when seen in the Z direction, a plurality of gap portions (gaps) 15a that extend to the -X side are formed on an edge of the source electrode 15 on the +X side. The plurality of gap portions 15a are arranged at intervals in the Y direction. When seen in the Z direction, end portions of the plurality of gap portions 15a on the -X side overlap the formation region 2. The end portions of the plurality of gap portions 15a on the -X side are located on the +X side with respect to the field plate electrodes 6 in the plurality of second FP trenches 4B. When seen in the Z direction, each of the plurality of gap portions 15a is disposed between the field plate electrodes 6 in the first FP trenches 4A adjacent to each other in the Y direction. A portion of the edge of the source electrode 15 on the +X side other than a portion on which the gap portions 15a are formed is located on the +X side with respect to the formation region 2 when seen in the Z direction.

When seen in the Z direction, a plurality of gap portions 15b that extend to the -Y side are formed on an edge of the source electrode 15 on the +Y side. The plurality of gap portions 15b are arranged at intervals in the X direction. When seen in the Z direction, end portions of the plurality of gap portions 15b on the -Y side overlap the formation region 2. The end portions of the plurality of gap portions 15b on the -Y side are located on the +Y side with respect to the field plate electrodes 6 in the plurality of second FP trenches 4B. When seen in the Z direction, each of the plurality of gap portions 15b is disposed between the field plate electrodes 6 in the first FP trenches 4A adjacent to each other in the X direction. A portion of the edge of the source electrode 15 on the +Y side other than a portion on which the gap portions 15b are formed is located on the +Y side with respect to the formation region 2 when seen in the Z direction. A part of a nitride film 40 is formed inside each of the gap portions 15a and 15b.

As shown in FIG. 2, the nitride film 40 is formed on a portion of the surface of the insulation film 42 on the +Z side other than a portion on which the source electrode 15 is formed. The nitride film 40 is made of, for example, silicon nitride. The nitride film 40 is formed by, for example, a plasma CVD method. A contact wiring 35GX is formed on a surface of the nitride film 40 on the +Z side. The contact wiring 35GX is made of a metal. The contact wiring 35GX is made of, for example, aluminum. The contact wiring 35GX may be made of a metal other than aluminum, such as copper. The contact wiring 35GX is exposed on the surface of the semiconductor device 1. Although not shown, a contact wiring 35GY is formed on the surface of the nitride film 40 on the +Z side. A material for forming the contact wiring 35GY is the same as the material for forming the contact wiring 35GX. The contact wiring 35GY is exposed on the surface of the semiconductor device 1. In FIG. 1, the contact wiring 35GX and the contact wiring 35GY are indicated by two-dot chain lines.

The gate trench 23 is recessed from the surface of the semiconductor member 1A on the +Z side to the -Z side. As shown in FIG. 1, in the first embodiment, the gate trench 23 is provided in a lattice shape, when seen in the Z direction, in which a plurality of first trench portions 23a that extend in the X direction and are arranged at intervals in the Y direction intersect a plurality of second trench portions 23b that extend in the Y direction and are arranged at intervals in the X direction. The entire gate trench 23 overlaps the formation region 2 when seen in the Z direction. End portions of the plurality of first trench portions 23a on the +X side are located on the +X side with respect to the field plate electrodes 6 in the plurality of second FP trenches 4B located furthest on the +X side. End portions of the plurality of second trench portions 23b on the +Y side are located on the +Y side with respect to the field plate electrode 6 in the plurality of second FP trenches 4B located furthest on the +Y side.

As shown in FIG. 3, the gate electrode 10 and a gate insulation film 9 are located inside the gate trench 23. At least a part of the gate electrode 10 is located inside the semiconductor member 1A. The gate electrode 10 is made of, for example, polysilicon. The gate electrode 10 may be made of a metal such as tungsten. When the gate electrode 10 is made of a metal such as tungsten, a high-temperature heat treatment performed in manufacture of the semiconductor device 1 is performed before the gate electrode 10 is formed. The high-temperature heat treatment is, for example, a heat treatment at a temperature higher than 100° C. As shown in FIG. 1, the gate electrode 10 has a plurality of first extension portions 10a and a plurality of first extension portions 10b. The plurality of first extension portions (first extensions) 10a extend in the X direction and are arranged at intervals in the Y direction. The plurality of first extension portions 10b extend in the Y direction and are arranged at intervals in the X direction. When seen in the Z direction, the gate electrode 10 is provided in a lattice shape in which the plurality of first extension portions 10a that extend in the X direction and are arranged at intervals in the Y direction intersect the plurality of first extension portions 10b that extend in the Y direction and are arranged at intervals in the X direction. The plurality of first extension portions 10a are located inside the first trench portions 23a, respectively. The plurality of first extension portions 10b are located inside the second trench portions 23b, respectively. The entire gate electrode 10 overlaps the formation region 2 when seen in the Z direction. End portions of the plurality of first extension portions 10a on the +X side are located on the +X side with respect to the field plate electrodes 6 in the plurality of second FP trenches 4B located furthest on the +X side. End portions of the plurality of first extension portions 10b on the +Y side are located on the +Y side with respect to the field plate electrodes 6 in the plurality of second FP trenches 4B located furthest on the +Y side. As shown in FIG. 2, the insulation film 42 is formed on the +Z side of the gate electrode 10.

The gate insulation film 9 is, for example, a silicon oxide film. The gate insulation film 9 is, for example, a film formed of a silicon compound. The gate insulation film 9 is, for example, a TEOS film formed using tetraethoxysilane as a raw material. The gate insulation film 9 is formed by, for example, a plasma CVD method. The gate insulation film 9 is formed on the entire inner surface of the gate trench 23. The gate insulation film 9 is connected to the insulation film 42. The gate electrode 10 is embedded in the semiconductor member 1A in a state in which it is insulated from the semiconductor member 1A via the gate insulation film 9. In the first embodiment, the gate insulation film 9 corresponds to the “second insulation film.” At least a part of the gate electrode 10 is disposed adjacent to the source layer 8 and the base layer 7 via the gate insulation film 9. In the first embodiment, a center portion of each of the first extension portions 10a in the Z direction is disposed adjacent to the source layer 8 and the base layer 7 in the Y direction via the gate insulation film 9. The center portion in the Z direction of each of the first extension portions 10b is disposed adjacent to the source layer 8 and the base layer 7 in the X direction via the gate insulation film 9. In the first embodiment, the gate electrode 10 formed in a lattice shape divides the source layer 8 and the base layer 7.

The semiconductor device 1 includes a gate wiring 33 electrically connected to the gate electrode 10. The gate wiring 33 is made of, for example, polysilicon. The gate wiring 33 may be made of, for example, a metal. The gate wiring 33 may be made of, for example, tungsten. The gate wiring 33 may be made of a metal other than tungsten. When the gate wiring 33 is made of a metal such as tungsten, the high-temperature heat treatment performed in the manufacture of the semiconductor device 1 is performed before the gate wiring 33 is formed. As shown in FIG. 1, in the first embodiment, a plurality of gate wirings 33 are provided. The plurality of gate wirings 33 include a gate wiring 33X connected to the plurality of first extension portions 10a and a gate wiring 33Y connected to the plurality of first extension portions 10b. The gate wiring 33Y is similar to the gate wiring 33X, except that an orientation thereof when seen in the Z direction is rotated 90° around an axis extending in the Z direction with respect to the gate wiring 33X, and that the gate wiring 33Y is connected to the plurality of first extension portions 10b. Therefore, in the following description, the gate wiring 33X will be described as a representative of the gate wirings 33X and 33Y, and a description of the gate wiring 33Y may be omitted. In FIG. 1, the gate wirings 33X and 33Y are indicated by two-dot chain lines.

The gate wiring 33X has a base portion 33a and a plurality of second extension portions (second extensions) 33b. The base portion 33a of the gate wiring 33X extends in the Y direction. The base portion 33a is located outside the formation region 2 when seen in the Z direction. The plurality of second extension portions 33b extend in the X direction. The plurality of second extension portions 33b extend from the base portion 33a to the -X side. The plurality of second extension portions 33b are arranged at intervals in the Y direction. Each of the plurality of second extension portions 33b extends in the X direction between the field plate electrodes 6 in the first FP trenches 4A adjacent to each other in the Y direction when seen in the Z direction. A portion of each of the second extension portions 33b on the -X side overlaps the formation region 2 when seen in the Z direction. An end portion of each of the second extension portion 33b on the -X side is located on the -X side with respect to the field plate electrode 6 in the plurality of first FP trenches 4A disposed at the end on the +X side. At least a part of each of the second extension portions 33b overlaps each of the gap portions 15a when seen in the Z direction. Therefore, a region in which the second extension portion 33b and the source electrode 15 overlap in the Z direction may be reduced by an amount in which the second extension portion 33b overlaps the gap portion 15a when seen in the Z direction. Thus, a parasitic capacitance between the source electrode 15 and the gate wiring 33X can be reduced. In the first embodiment, a part of the portion of each of the second extension portions 33b on the -X side overlaps each of the gap portions 15a formed in the source electrode 15 when seen in the Z direction.

As shown in FIG. 3, each of the second extension portions 33b is located on the +Z side with respect to the gate electrode 10. Each of the second extension portions 33b is disposed at a different position from the source electrode 15 in the Z direction. In the first embodiment, each of the second extension portions 33b is located on the -Z side with respect to the source electrode 15. Each of the second extension portions 33b is electrically connected to the gate electrode 10 via a contact 41. The contact 41 is formed of, for example, polysilicon. The contact 41 may be made of, for example, a metal such as tungsten. When the contact 41 is made of a metal such as tungsten, the high-temperature heat treatment performed in the manufacture of the semiconductor device 1 is performed before the contact 41 is formed. In the first embodiment, the end portion of each of the first extension portion 10a on the +X side is electrically connected to the end portion of each of the second extension portions 33b on the -X side via the contact 41. The end portion of the first extension portion 10a on the +X side is located inside the formation region 2 when seen in the Z direction. That is, each of the second extension portions 33b is connected to each of the first extension portions 10a of the gate electrode 10 at a position inside the formation region 2 in which the plurality of field plate electrodes 6 are formed, when seen in the Z direction. Each of the second extension portions 33b extends in the +X direction from a portion connected to each of the first extension portions 10a of the gate electrode 10 to a position outside the formation region 2 when seen in the Z direction. Each of the contacts 41 is located on the -X side with respect to the field plate electrode 6 located furthest on the +X side, and is located on the +X side with respect to the field plate electrode 6 adjacent to the -X side of the field plate electrode 6 located furthest on the +X side. Thus, each of the first extension portions 10a and each of the second extension portions 33b are connected to each other at a position in the X direction between the field plate electrode 6 that is located furthest on the +X side in the X direction among the plurality of field plate electrodes 6 and the field plate electrode 6 disposed adjacent to the -X side of the field plate electrode that is located furthest on the +X side.

The base portion 33a is disposed at the same position as the second extension portion 33b in the Z direction. The base portion 33a may be disposed at a different position in the Z direction from the second extension portion 33b. The base portion 33a is electrically connected to the contact wiring 35GX via a contact 34X. The contact 34X is made of, for example, a metal. The contact 34X is formed of, for example, a Ti/TiN/W laminated film. The contact 34X may be made of other metals. The gate wiring 33X is connected to the contact wiring 35GX via the contact 34X at a position outside the formation region 2 when seen in the Z direction. The contact 34X penetrates the nitride film 40 in the Z direction and is electrically connected to the contact wiring 35GX. The gate wiring 33X is connected to the contact wiring 35GX via the contact 34X. Thus, the contact wiring 35GX is electrically connected to the gate electrode 10 via the contact 34X, the gate wiring 33X, and the contact 41.

As shown in FIG. 1, the gate wiring 33Y has a base portion 33c and a plurality of second extension portions 33d. Although not shown, each of the second extension portions 33d is electrically connected to the gate electrode 10 via a contact, similar to each of the second extension portions 33b. The plurality of second extension portions 33d are connected to the plurality of first extension portions 10b, respectively. The base portion 33c of the gate wiring 33Y is electrically connected to the contact wiring 35GY via a contact 34Y, similar to the base portion 33a of the gate wiring 33X. A material forming the contact 34Y is, for example, the same as the material forming the contact 34X. The gate wiring 33Y is connected to the contact wiring 35GY via the contact 34Y at a position outside the formation region 2 when seen in the Z direction. Although not shown in the drawing, the contact 34Y penetrates the nitride film 40 in the Z direction and is electrically connected to the contact wiring 35GY. The gate wiring 33Y is connected to the contact wiring 35GY via the contact 34Y. Thus, the contact wiring 35GY is electrically connected to the gate electrode 10 via the contact 34Y, the gate wiring 33Y, and a contact (not shown).

In the gate wiring 33X, the X direction corresponds to a “second direction” that intersects the first direction, and the Y direction corresponds to a “third direction” that intersects both the first and second directions. In the gate wiring 33X, the side (the +X side) to which an arrow indicating the X direction faces corresponds to “one side in the second direction,” and the side (the -X side) opposite to the side to which the arrow indicating the X direction faces corresponds to “the other side in the second direction.” On the other hand, in the gate wiring 33Y, the Y direction corresponds to the “second direction” intersecting the first direction, and the X direction corresponds to the “third direction” intersecting both the first and second directions. In the gate wiring 33Y, the side (the +Y side) to which an arrow indicating the Y direction faces corresponds to “one side in the second direction,” and the side (the -Y side) opposite to the side to which the arrow indicating the Y direction faces corresponds to “the other side in the second direction.” The second direction in the gate wiring 33X is different from the second direction in the gate wiring 33Y. The third direction in the gate wiring 33X is different from the third direction in the gate wiring 33Y.

For example, when each of the second extension portions 33b of the gate wiring 33X is connected to each of the first extension portions 10a of the gate electrode 10 at a position inside the formation region 2 when seen in the Z direction, a case in which a position of the source electrode 15 in the Z direction and a position of the second extension portion 33b in the Z direction are the same is considered. In this case, for example, it is conceivable to form each of the second extension portions 33b in each of the gap portions 15a formed in the source electrode 15, and connect the second extension portion 33b to the gate electrode 10 at a position inside the formation region 2 when seen in the Z direction, while avoiding a short circuit between the source electrode 15 and the second extension portion 33b. In this case, however, an edge of each of the gap portions 15a of the source electrode 15 in the Y direction and an edge of the second extension portion 33b in the Y direction have to be sufficiently separated to avoid a short circuit. Thus, it is necessary to provide a relatively large distance in the Y direction between the edge of each of the gap portion 15a of the source electrode 15 in the Y direction and the edge of the second extension portion 33b in the Y direction. Therefore, when a width of the second extension portion 33b in the Y direction is not changed, it is necessary to increase a distance in the Y direction between the second extension portions 33b by an amount that the distance in the Y direction between the edge of each of the gap portions 15a in the Y direction and the edge of each of the second extension portions 33b in the Y direction has to be increased. As a result, a restriction arises in that it becomes difficult to reduce a pitch between the second extension portions 33b in the Y direction. Thus, it was difficult to reduce the pitch in the Y direction between the plurality of first extension portions 10a of the gate electrode 10, so there was a problem in that it is difficult to reduce a cell pitch in the semiconductor device 1.

On the other hand, in the first embodiment, the source electrode 15 and the plurality of second extension portions 33b are disposed at different positions in the Z direction. That is, the source electrode 15 and the plurality of second extension portions 33b are disposed in layers at different levels. Therefore, the source electrode 15 and the plurality of second extension portions 33b may be disposed without considering short circuits. Thus, it is possible to freely arrange the edges of the plurality of second extension portions 33b in the Y direction relative to the edges of the gap portions 15a in the Y direction, and the distance between the plurality of second extension portions 33b in the Y direction may be reduced. Therefore, when the width of the plurality of second extension portions 33b in the Y direction is not changed, the pitch between the plurality of second extension portions 33b in the Y direction may be made smaller, and any restrictions on the pitch between the plurality of second extension portions 33b in the Y direction may be curbed. Therefore, the pitch in the Y direction between the plurality of first extension portions 10a to which the plurality of second extension portions 33b are respectively connected may be made smaller, and the cell pitch in the semiconductor device 1 may be made smaller. In this way, according to the first embodiment, restrictions on the cell pitch in the semiconductor device 1 can be curbed.

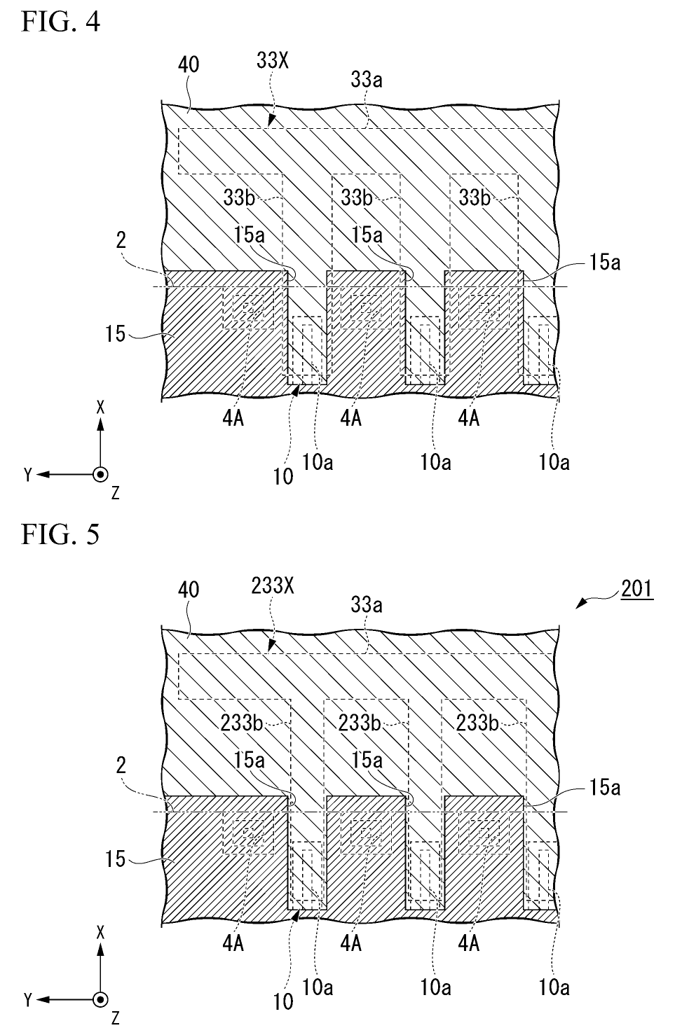

FIG. 4 is an enlarged plan view of the source electrode 15 and the end portion of the gate wiring 33X. In the first embodiment, as shown in FIG. 4, at least a part of each of the second extension portions 33b overlaps the source electrode 15 when seen in the Z direction. Therefore, compared to a case in which each of the second extension portions 33b is disposed so that the entirety of the second extension portion 33b does not overlap the source electrode 15 when seen in the Z direction, restrictions on the shape, width, and the like of each of the second extension portions 33b can be curbed. Thus, the wiring resistance of the gate wiring 33X is easily reduced by increasing the width of each of the second extension portions 33b. In the first embodiment, both edges in the Y direction of a portion of each of the second extension portions 33b that is disposed at the same position as the gap portion 15a in the X direction overlap the source electrode 15 when seen in the Z direction. Therefore, when the width of the second extension portion 33b in the Y direction is not changed, the pitch between the plurality of second extension portions 33b in the Y direction can be made smaller, and the restrictions on the cell pitch in the semiconductor device 1 can be further curbed, compared to the case in which the entirety of each of the second extension portions 33b does not overlap the source electrode 15 when seen in the Z direction. Furthermore, when the pitch between the second extension portions 33b is not changed, the width of the second extension portions 33b in the Y direction can be made larger, compared to the case in which the entire of each of the second extension portions 33b does not overlap the source electrode 15 when seen in the Z direction. Thus, the resistance of the gate wiring 33X can be reduced. In addition, since a part of the second extension portion 33b overlaps the gap portion 15a when seen in the Z direction, it is possible to curb an increase in the parasitic capacitance generated between the source electrode 15 and the gate wiring 33X compared to a case in which the gap portion 15a is not formed.

In the source electrode 15 and the second extension portion 33b of the gate wiring 33X shown in FIG. 4, a parasitic capacitance is generated in a portion in which they overlap each other when seen in the Z direction. However, when an effect of the parasitic capacitance in the semiconductor device 1 is so slight that the parasitic capacitance does not affect an operation required in the semiconductor device 1, the arrangement of the source electrode 15 and the second extension portion 33b of the gate wiring 33X as shown in FIG. 4 may be adopted.

Here, for example, when the gate electrode 10 is connected to the gate wiring 33X outside the formation region 2 when seen in the Z direction, a potential of the drain electrode 36 is applied to the gate electrode 10 via the drift layer 39 and the gate insulation film 9 that are not depleted by the plurality of field plate electrodes 6. The gate insulation film 9 is often thinner than other insulation films, and when the drift layer 39 is not depleted and the potential of the drain electrode 36 is applied, there is a risk of dielectric breakdown. In contrast, by connecting the gate electrode 10 to the gate wiring 33X at a position inside the formation region 2 when seen in the Z direction, a portion of the drift layer 39 that is disposed with the gate insulation film 9 interposed between the gate electrode 10 and the portion of the drift layer 39 is depleted by the plurality of field plate electrodes 6, and thus, the dielectric breakdown of the gate insulation film 9 can be curbed without the potential of the drain electrode 36 being directly applied to the gate insulation film 9. Since there are no restrictions such as the need to make the thickness of the insulation film formed relatively thinner, as in the gate insulation film 9, outside a region in which the gate electrode 10 is provided when seen in the Z direction, an insulation film thicker than the gate insulation film 9 may be provided. Therefore, a relatively thick insulation film may be provided between the drift layer 39 and the portion of the gate wiring 33X that is provided in the region outside the formation region 2 when seen in the Z direction. Therefore, even when the second extension portion 33b is provided closer to the drift layer 39 in the Z direction than the source electrode 15, the insulation film provided between the second extension portion 33b and the drift layer 39 may be made thick enough to prevent the dielectric breakdown.

In the first embodiment, as described above, each of the first extension portions 10a and each of the second extension portions 33b are connected to each other at a position in the X direction between the field plate electrode 6 located furthest on the +X side in the X direction among the plurality of field plate electrodes 6 and the field plate electrode 6 located adjacent to the -X side of the field plate electrode located furthest on the +X side. Therefore, it is easy to increase a dimension of the first extension portion 10a in the X direction while connecting the gate electrode 10 to the gate wiring 33X at a position inside the formation region 2 when seen in the Z direction.

In the first embodiment, as described above, when seen in the Z direction, the outer edge of the formation region 2 passes through the outer edges of all of the source contacts 14 located at both ends in the X direction among the plurality of source contacts 14, and the outer edges of all of the source contacts 14 located at both ends in the Y direction among the plurality of source contacts 14. When seen in the Z direction, by connecting the gate electrode 10 and the gate wiring 33X at a position inside the formation region 2 defined in this way, it is possible to more easily curb the potential of the drain electrode 36 from being directly applied to the gate insulation film 9, as described above. Thus, it is possible to effectively curb the gate insulation film 9 from being broken down.

As shown in FIG. 3, the semiconductor device 1 includes the third insulation film 38 of which at least a part is located outside the formation region 2 when seen in the Z direction. In the first embodiment, almost the entire third insulation film 38 is located outside the formation region 2 when seen in the Z direction. The third insulation film 38 is located between the semiconductor member 1A and the plurality of second extension portions 33b of the gate wiring 33X in the Z direction. In the first embodiment, the third insulation film 38 is located between the protective film 32 and the drift layer 39 in the Z direction. The third insulation film 38 is thicker than the gate insulation film 9. By arranging the third insulation film 38, which is thicker than the gate insulation film 9, between the semiconductor member 1A and the plurality of second extension portions 33b in the Z direction, it becomes easier to ensure insulating properties between the drift layer 39 and the gate wiring 33X. Therefore, the occurrence of dielectric breakdown between the gate wiring 33X and the drift layer 39 can be further curbed.

There are no particular limitations on a material of the third insulation film 38 as long as the material has insulating properties. The third insulation film 38 may be made of the same material as the field plate insulation film 5, for example. As an example, the field plate insulation film 5 is formed as a silicon oxide film by a thermal oxidation or CVD method on the entire surface of the semiconductor member 1A on the +Z side on which the plurality of FP trenches 4 are formed. Then, in the silicon oxide film except for the silicon oxide film provided in the FP trench 4, the silicon oxide film located outside the formation region 2 when seen in the Z direction is left, and the other silicon oxide film is removed by etching or the like. Thus, the third insulation film 38 may be easily disposed without performing a separate film-forming step.

When the plurality of second extension portions 33b of the gate wiring 33X are disposed at different positions in the Z direction from the source electrode 15, a positional relationship in the Z direction between the portion of the gate wiring 33X other than the plurality of second extension portions 33b and the source electrode 15 is not particularly limited. As long as each of the second extension portions 33b is connected to each of the first extension portions 10a of the gate electrode 10 and extends from the inside to the outside of the formation region 2, any configuration may be used. For example, the gate wiring 33X may have another portion formed therein that connects the plurality of second extension portions 33b and the base portion 33a, and the other portion and the base portion 33a may be disposed at different positions in the Z direction from the plurality of second extension portions 33b.

### Second embodiment

A configuration of the semiconductor device 201 according to a second embodiment will be described below. FIG. 5 is an enlarged plan view of a source electrode 15 and an end portion of the gate wiring 233X according to the second embodiment. In this drawing, the same components as those of the semiconductor device 1 of the first embodiment shown in FIGS. 1 to 4 are designated by the same reference numerals, and the description thereof will be omitted. The second embodiment differs from the first embodiment in a configuration of the source electrode 15 and the gate wiring 233X.

As shown in FIG. 5, an entire portion of a second extension portion 233b of the gate wiring 233X that is disposed at the same position as the gap portion 15a in the X direction overlaps the gap portion 15a when seen in the Z direction. In the second embodiment, the entire second extension portion 233b does not overlap the source electrode 15 when seen in the Z direction. A width of the second extension portion 233b in the Y direction is smaller than a width of the gap portion 15a in the Y direction. Therefore, when seen in the Z direction, the source electrode 15 and the second extension portion 233b are disposed with a distance therebetween. Both ends of the second extension portion 233b in the Y direction are disposed apart from the source electrode 15 when seen in the Z direction. Similar to the second extension portion 33b in the first embodiment, since the second extension portion 233b is disposed at a different position in the Z direction from the source electrode 15, there is no need to consider insulation between the second extension portion 233b and the source electrode 15. Therefore, a distance between the source electrode 15 and the second extension portion 233b when seen in the Z direction can be made smaller than when the second extension portion 233b and the source electrode 15 are disposed at the same position in the Z direction. The other configuration is similar to that of the semiconductor device 1 in the first embodiment.

According to the second embodiment, the entire portion of the second extension portion 233b that is disposed at the same position as the gap portion 15a in the X direction (the second direction) overlaps the gap portion 15a when seen in the Z direction. Therefore, it is possible to suppress the generation of the parasitic capacitance between the source electrode 15 and the gate wiring 233X. Furthermore, according to the second embodiment, the entire second extension portion 233b does not overlap the source electrode 15 when seen in the Z direction. Therefore, it is possible to further curb the generation of the parasitic capacitance between the source electrode 15 and the gate wiring 233X.

### Third embodiment

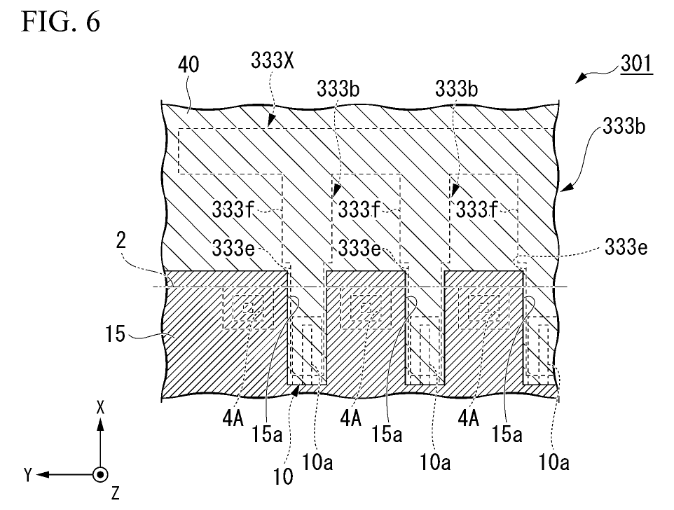

A configuration of a semiconductor device 301 according to a third embodiment will be described below. FIG. 6 is an enlarged plan view of a source electrode 15 and an end portion of a gate wiring 333X according to the third embodiment. In this drawing, the same components as those of the semiconductor device 1 of the first embodiment shown in FIGS. 1 to 4 are designated by the same reference numerals, and the description thereof will be omitted. The third embodiment differs from the first embodiment in a configuration of the source electrode 15 and the gate wiring 333X.

As shown in FIG. 6, in the gate wiring 333X, a second extension portion 333b has a width in the Y direction that changes in the X direction. Each of the second extension portions 333b has a first portion 333e and a second portion 333f. The first portion 333e and the second portion 333f extend in the X-direction. The first portion 333e is a portion of the second extension portion 333b on the -X side. The first portion 333e has a portion connected to the gate electrode 10. An end portion of the first portion 333e on the +X side is located on the +X side with respect to the source electrode 15. The first portion 333e has a portion that is located at the same position as the gap portion 15a in the X direction. A width of the first portion 333e in the Y direction is equal to or smaller than a width of the gap portion 15a in the Y direction. In the third embodiment, the width of the first portion 333e in the Y direction is smaller than the width of the gap portion 15a in the Y direction. The entire portion of the first portion 333e that is disposed at the same position as the gap portion 15a in the X direction overlaps the gap portion 15a when seen in the Z direction. In other words, the first portion 333e does not overlap the source electrode 15 when seen in the Z direction. Both ends of the first portion 333e in the Y direction are disposed apart from the source electrode 15 when seen in the Z direction. The second portion 333f is a portion of the second extension portion 333b on the +X side. The second portion 333f is connected to an end portion of the first portion 333e on the +X side. The second portion 333f is located on the +X side with respect to the source electrode 15. A width of the second portion 333f in the Y direction is larger than the width in the Y direction of the first portion 333e. The width of the second portion 333f in the Y direction is larger than the width in the Y direction of the gap portion 15a. The other configurations are similar to those of the semiconductor device 1 in the first embodiment.

According to the third embodiment, the entire portion of the first portion 333e that is disposed at the same position as the gap portion 15a in the X direction (the second direction) overlaps the gap portion 15a when seen in the Z direction. The width of the second portion 333f in the Y direction (the third direction) is greater than the width of the first portion 333e in the Y direction and is also greater than the width of the gap portion 15a in the Y direction. Therefore, it is possible to curb the generation of the parasitic capacitance between the source electrode 15 and the first portion 333e, and also possible to make the second portion 333f larger in the Y direction, thereby reducing the wiring resistance in the gate wiring 333X.

According to at least one of the embodiments described above, the semiconductor device includes a semiconductor member having a drift layer having a first conductivity type, a source electrode located on one side of the semiconductor member in a first direction, a drain electrode located on the other side of the semiconductor member in the first direction, a plurality of field plate electrodes that extend in the first direction and at least parts of which are located inside the drift layer, a gate electrode at least a part of which is located inside the semiconductor member, and a gate wiring electrically connected to the gate electrode. The plurality of field plate electrodes are electrically connected to the source electrode, insulated from the semiconductor member via a first insulation film, and disposed to be spaced apart from each other at a plurality of locations in a second direction intersecting the first direction and a third direction intersecting both the first and second directions. The semiconductor member has a base layer located on one side of the drift layer in the first direction and having a second conductivity type, and a source layer located on one side of the base layer in the first direction and having the first conductivity type. The gate electrode has a plurality of first extension portions extending in the second direction and is insulated from the semiconductor member via a second insulation film. The plurality of first extension portions are arranged at intervals in the third direction. At least a part of the gate electrode is disposed adjacent to the source layer and the base layer via the second insulation film. The source layer is electrically connected to the source electrode. The source electrode extends along a plane perpendicular to the first direction. The gate wiring has a plurality of second extension portions that extend in the second direction. The plurality of second extension portions are arranged at intervals in the third direction. Each second extension portion is connected to a corresponding first extension portion at a position that is inside a formation region in which the plurality of field plate electrodes are formed when seen in the first direction, and extends to one side in the second direction from a portion connected to each of the first extension portions to a position that is outside the formation region when seen in the first direction. The source electrode and the second extension portions are disposed at different positions in the first direction. Thus, since it is no longer necessary to consider short circuits between the source electrode and the plurality of second extension portions of the gate wiring, as described above, the restrictions on the cell pitch in the semiconductor device can be curbed.

When at least a part of each of the plurality of second extension portions overlaps the source electrode when seen in the first direction, it is sufficient that at least parts of one or more of the plurality of second extension portions overlap the source electrode when seen in the first direction. A portion of the second extension portion that overlaps the source electrode when seen in the first direction may be any portion of the second extension portion. For example, an end portion of the second extension portion in the second direction may overlap the source electrode when seen in the first direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor member having a drift layer having a first conductivity type;
a source electrode located on one side in a first direction of the semiconductor member;
a drain electrode located on the other side in the first direction of the semiconductor member;
a plurality of field plate electrodes that extend in the first direction and at least parts of which are located inside the drift layer;
a gate electrode at least a part of which is located inside the semiconductor member; and
a gate wiring electrically connected to the gate electrode,
wherein the plurality of field plate electrodes are electrically connected to the source electrode, insulated from the semiconductor member via a first insulation film, and disposed to be spaced apart from each other at a plurality of locations in a second direction intersecting the first direction and a third direction intersecting both the first direction and the second direction,
the semiconductor member includes:
a base layer located on the one side in the first direction of the drift layer and having a second conductivity type; and
a source layer located on the one side in the first direction of the base layer and having the first conductivity type,
the gate electrode has a plurality of first extensions extending in the second direction and is insulated from the semiconductor member via a second insulation film,
the plurality of first extensions are arranged at intervals in the third direction,
at least a part of the gate electrode is disposed adjacent to the source layer and the base layer via the second insulation film,
the source layer is electrically connected to the source electrode,
the source electrode extends along a plane perpendicular to the first direction,
the gate wiring has a plurality of second extensions that extend in the second direction,
the second extensions are arranged at intervals in the third direction,
each second extension is connected to a corresponding first extension at a position inside a formation region in which the plurality of field plate electrodes are formed when seen in the first direction, and extends on one side in the second direction from a portion connected to each of the first extensions to a position outside the formation region when seen in the first direction, and
the source electrode and the plurality of second extensions are disposed at different positions in the first direction.

2. The semiconductor device of claim 1, wherein a plurality of gaps that extend to the other side in the second direction are formed at an edge of the source electrode on the one side in the second direction,
the plurality of gaps are arranged at intervals in the third direction, and
at least a part of each of the second extensions overlaps each of the gaps when seen in the first direction.

3. The semiconductor device of claim 2, wherein both edges in the third direction of a portion of each of the second extensions that is disposed at the same position as each of the gaps in the second direction overlap the source electrode when seen in the first direction.

4. The semiconductor device of claim 2, wherein
a width of each of the second extensions in the third direction is smaller than a width of each of the gap portions in the third direction,
both ends of each of the second extensions in the third direction are disposed apart from the source electrode when seen in the first direction, and an entire portion of each of the second extensions that is disposed at the same position as each of the gaps in the second direction overlaps each of the gaps when seen in the first direction.

5. The semiconductor device of claim 2, wherein each of the second extensions includes:
a first portion having a portion connected to the first extension and configured to extend in the second direction; and
a second portion connected to an end portion of the first portion on the one side in the second direction and configured to extend in the second direction,
the second portion is located on the one side in the second direction with respect to the source electrode,
a width of the first portion in the third direction is smaller than a width of the gap portion in the third direction,
both ends of the first portion in the third direction are disposed apart from the source electrode when seen in the first direction,
an entire portion of the first portion that is disposed at the same position as the gap in the second direction overlaps the gap when seen in the first direction, and
a width of the second portion in the third direction is larger than a width of the first portion in the third direction and is also larger than a width of the gap in the third direction.

6. The semiconductor device of claim 1, wherein at least a part of each of the plurality of second extensions overlaps the source electrode when seen in the first direction.

7. The semiconductor device of claim 1, wherein each of the second extensions does not entirely overlap the source electrode when seen in the first direction.

8. The semiconductor device of claim 1, further comprising a third insulation film at least a part of which is located outside the formation region when seen in the first direction,
wherein the third insulation film is located between the semiconductor member and the plurality of second extensions in the first direction, and
the third insulation film has a thickness greater than a thickness of the second insulation film.

9. The semiconductor device of claim 8, further comprising a protective film having a barrier property against ions,
wherein the protective film has a portion formed on a surface of the third insulation film on the one side in the first direction.

10. The semiconductor device of claim 1, wherein each of the first extensions and each of the second extensions are connected to each other at a position in the second direction between the field plate electrode that is located furthest on the one side in the second direction among the plurality of field plate electrodes and the field plate electrode disposed adjacent to the other side of the field plate electrode in the second direction that is located furthest on the one side in the second direction.

11. The semiconductor device of claim 1, further comprising a plurality of source contacts electrically connected to the source electrode,
wherein each of the source contacts is formed around each of the field plate electrodes when seen in the first direction, and
an outer edge of the formation region passes through outer edges of all of the source contacts that are located at both ends in the second direction, among the plurality of source contacts, and outer edges of all of the source contacts that are located at both ends in the third direction, among the plurality of source contacts when seen in the first direction.
